(19) United States
(12) Patent Application Publication
(10) Pub. No.: US 2025/0351951 A1
(43) Pub. Date: Nov. 20, 2025

(54) BRUSH AGING APPARATUS AND BRUSH AGING METHOD

(71) Applicant: Samsung Electronics Co., Ltd., Suwon-si (KR)

(72) Inventors: Yonghee LEE, Suwon-si (KR); Sunho Kim, Suwon-si (KR); Hyewon Kim, Suwon-si (KR)

(73) Assignee: SAMSUNG ELECTRONICS CO., LTD., Suwon-si (KR)

(21) Appl. No.: 19/077,706

(22) Filed: Mar. 12, 2025

(30) Foreign Application Priority Data
May 20, 2024 (KR) 10-2024-0065362

(51) Int. Cl. A46D 9/00; A46B 13/00; A46B 13/04; A46B 15/00; B24B 37/34; H01L 21/67

(52) U.S. Cl. CPC A46D 9/00; A46B 13/001; A46B 13/04; A46B 15/0004; B24B 37/34; A46B 2200/3073; H01L 21/67046

(57) ABSTRACT

A brush aging apparatus may include: a chamber configured to provide a process space; and inside the process space: a brush including a plurality of protrusions protruding in a direction perpendicular to a circumferential surface of the brush; a stand detachably coupled to the brush and configured to rotate the brush by taking a lengthwise direction of the brush as a rotation axis; an aging bar configured to abrade the plurality of protrusions; a driving member coupled to the aging bar and configured to move the aging bar to make the aging bar contact or be spaced apart from at least any one of the plurality of protrusions of the brush; a nozzle configured to discharge a cleaning solution to an interface where the brush contacts the aging bar; and a sensor spaced apart from the brush and configured to measure parameters of the plurality of protrusions.

### CROSS-REFERENCE TO RELATED APPLICATION

This application is based on and claims priority under 35 U.S.C. §119 to Korean Patent Application No. 10-2024-0065362, filed on May 20, 2024, in the Korean Intellectual Property Office, the disclosure of which is incorporated by reference herein in its entirety.

### BACKGROUND

### 1. Field

The disclosure relates to a brush aging apparatus and a brush aging method, and more particularly, to a brush aging apparatus for aging a new brush and a brush aging method.

### 2. Description of Related Art

Among semiconductor manufacturing processes, the chemical mechanical polishing (CMP) process is a process of using a chemical solution, called slurry, and a polishing pad to cause a chemical reaction with a wafer while simultaneously applying mechanical power to the wafer to flatten the wafer.

A cleaning process may be performed after the CMP process to remove particles and oxidized residues left on the wafer surface. A substrate cleaning apparatus for performing the cleaning process may include a pair of brushes and a plurality of injection nozzles, wherein the brushes slidably contact both surfaces of the wafer for cleaning, and the injection nozzles spray a cleaning solution onto both surfaces of the wafer.

### SUMMARY

In this case, before a new brush is installed on the substrate cleaning apparatus, it can be beneficial to age the new brush to prevent the new brush from damaging the wafer or generating particles and the like.

The disclosure provides a brush aging apparatus with improved aging accuracy and reduced process time, and a brush aging method.

Technical problems to be solved by the disclosure are not limited to the above description, and other technical problems may be clearly understood by one of ordinary skill in the art from the descriptions provided hereinafter.

According to one or more example embodiments, a brush aging apparatus may include: a chamber configured to provide a process space; and inside the process space: a brush including a plurality of protrusions protruding in a direction perpendicular to a circumferential surface of the brush; a stand detachably coupled to the brush and configured to rotate the brush by taking a lengthwise direction of the brush as a rotation axis; an aging bar configured to abrade the plurality of protrusions; a driving member coupled to the aging bar and configured to move the aging bar to make the aging bar contact or be spaced apart from at least any one of the plurality of protrusions of the brush; a nozzle configured to discharge a cleaning solution to an interface where the brush contacts the aging bar; and a sensor spaced apart from the brush and configured to measure parameters of the plurality of protrusions.

According to one or more example embodiments, a brush aging method may include: introducing a brush into a chamber, the brush being a new brush; measuring a parameter of a protrusion of the new brush through a sensor inside the chamber; performing aging for the brush based on the parameter to convert the new brush into an aged brush; measuring the parameter of the protrusion of the aged brush through the sensor; determining, by using at least one processor, whether the parameter has reached a target parameter; when the parameter fails to reach the target parameter, performing again the aging for the aged brush based on the parameter; and when the parameter reaches the target parameter, removing the aged brush from the chamber.

According to one or more example embodiments, a brush aging apparatus may include: a chamber configured to provide a process space. The apparatus may further include, inside the process space: a brush including a plurality of protrusions protruding in a direction perpendicular to a circumferential surface of the brush; a stand detachably coupled to the brush and configured to rotate the brush by taking a lengthwise direction of the brush as a rotation axis; an aging bar configured to abrade the plurality of protrusions, having a flat shape, and placed such that a flat surface of the aging bar faces the circumferential surface of the brush; a driving member coupled to a ceiling of the chamber and the aging bar and configured to move the aging bar in a vertical direction to make the aging bar come in contact with or be spaced apart from at least any one of the plurality of protrusions of the brush; a nozzle configured to discharge a cleaning solution to an interface where the brush contacts the aging bar; a sensor spaced apart from the brush and configured to measure parameters of the plurality of protrusions; a height adjusting member configured to adjust a location of the sensor in the vertical direction; and a rail extending in a direction parallel to the lengthwise direction of the brush and providing a path along which the sensor moves in the lengthwise direction of the brush. The apparatus may further include: at least one processor; and memory storing instructions that, when executed by the at least one processor, cause the at least one processor to control pressure applied to the brush by the aging bar and rotation speed of the brush, based on the parameters of the plurality of protrusions that are measured by the sensor. The parameters may include at least any one of a cross-sectional area of the plurality of protrusions of the brush according to a Y-Z plane, a height of the plurality of protrusions in a protrusion direction, a degree to which edges of the plurality of protrusions are rounded, and an amount of foreign materials left on a surface of the plurality of protrusions.

According to one or more example embodiments, a brush aging apparatus may include: a chamber configured to provide a process space. The apparatus may further include, inside the process space: a stand configured to: accommodate a brush including a plurality of protrusions protruding in a direction perpendicular to a circumferential surface of the brush; and rotate the brush by taking a lengthwise direction of the brush as a rotation axis; an aging bar configured to abrade the plurality of protrusions; and a sensor spaced apart from the brush and configured to measure a parameter of the plurality of protrusions. The apparatus may further include at least one processor; and memory storing instructions that, when executed by the at least one processor, cause the at least one processor to: obtain the parameter of the plurality of protrusions before performing an aging; control the stand and the aging bar to perform aging for the brush based on the parameter; obtain the parameter of the plurality of protrusions after performing the aging; determine whether the parameter has reached a target parameter; and when the parameter fails to reach the target parameter, control the stand and the aging bar to perform again the aging for the brush based on the parameter.

### BRIEF DESCRIPTION OF THE DRAWINGS

One or more embodiments will be more clearly understood from the following detailed description taken in conjunction with the accompanying drawings in which:

FIG. 1 is a schematic cross-sectional view of a brush aging apparatus according to one or more embodiments;

FIG. 2 is a schematic perspective view of the brush aging apparatus of FIG. 1;

FIG. 3 is a schematic side view of the brush aging apparatus of FIG. 1;

FIG. 4A schematically shows the operations of the brush aging apparatus of FIG. 1;

FIG. 4B schematically shows the operations of the brush aging apparatus of FIG. 1;

FIG. 5A is a cross-sectional view showing shape changes of protrusions, according to one or more embodiments;

FIG. 5B is a cross-sectional view showing shape changes of protrusions, according to one or more embodiments;

FIG. 6 schematically shows the operation of a sensor, according to one or more embodiments;

FIG. 7A schematically shows a region AA of FIG. 6;

FIG. 7B is a cross-sectional view taken along a line B-B′ of FIG. 6;

FIG. 8 is a schematic flowchart of a brush aging method;

FIG. 9A is a cross-sectional view showing shape changes of protrusions according to brush aging;

FIG. 9B is a cross-sectional view showing shape changes of protrusions according to brush aging;

FIG. 9C is a cross-sectional view showing shape changes of protrusions according to brush aging;

FIG. 10 is a schematic cross-sectional view of a brush aging apparatus according to one or more embodiments;

FIG. 11 is a schematic cross-sectional view of a brush aging apparatus according to one or more embodiments; and

FIG. 12 is a schematic cross-sectional view of a brush aging apparatus according to one or more embodiments.

### DETAILED DESCRIPTION

Hereinafter, one or more one or more embodiments of the disclosure will be described in detail with reference to the attached drawings. Like reference numerals in the drawings denote like elements, and repeated descriptions thereof will be omitted.

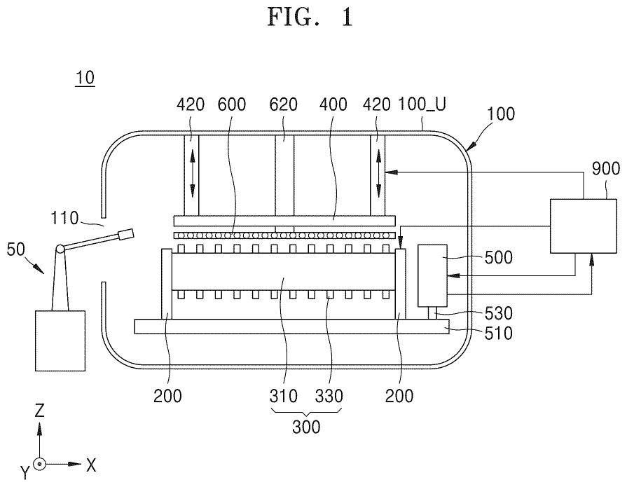

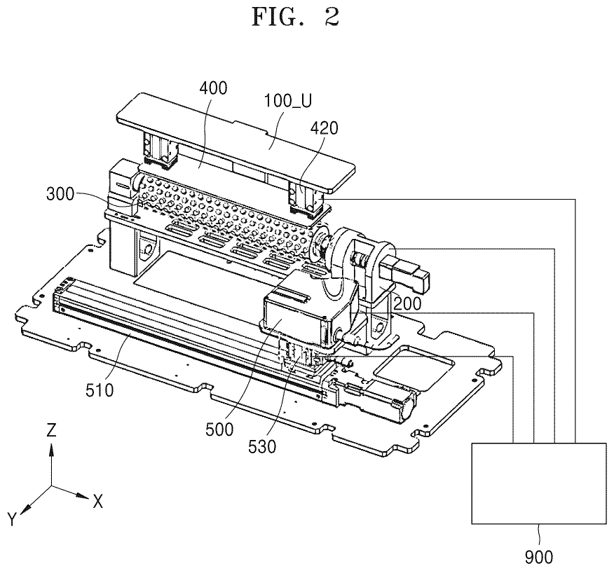

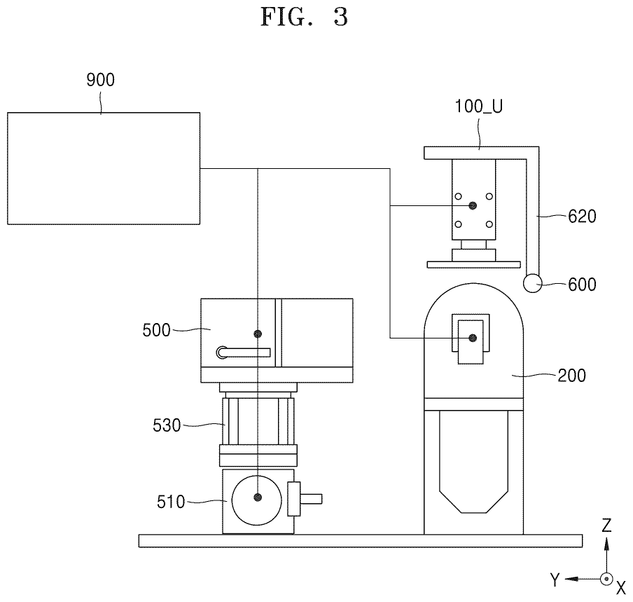

FIG. 1 is a schematic cross-sectional view of a brush aging apparatus 10 according to one or more embodiments. FIG. 2 is a schematic perspective view of the brush aging apparatus 10 of FIG. 1. FIG. 3 is a schematic side view of the brush aging apparatus 10 of FIG. 1.

Referring to FIGS. 1 to 3, the brush aging apparatus 10 may include a chamber 100, an interface robot 50, a brush 300, an aging bar 400, a stand 200, a nozzle 600, a sensor 500, and a controller 900.

The chamber 100 may include an internal process space. The chamber 100 may provide a space where the brush 300, the aging bar 400, the stand 200, the nozzle 600, and the sensor 500 may be accommodated.

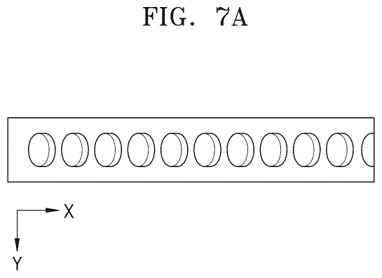

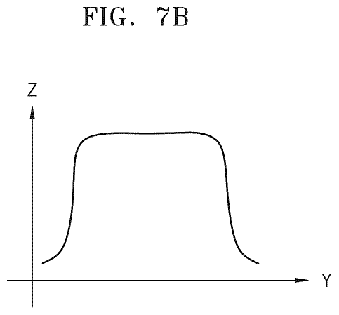

According to one or more embodiments, in the chamber 100 of the brush aging apparatus 10, an aging process of the brush 300 for cleaning a substrate may be performed. Here, the aging process may be a process of trimming the shape and surface of a new brush 300 or removing foreign materials before the new brush 300 is introduced into the process. For example, because of the aging process, the height of the new brush 300 may be reduced or angular edge portions of the new brush 300 may be rounded, which is described in detail with reference to FIGS. 7A and 7B. In addition, the new brush 300 may be a newly manufactured brush and may be understood as a new brush 300 that has never been introduced into processes including a cleaning process. However, the brush 300 aged by the brush aging apparatus 10 is not limited to new brushes 300, and in some one or more embodiments, a worn brush 300 may also be aged by the brush aging apparatus 10.

The interface robot 50 may be configured to introduce the brush 300 into the chamber 100 or remove the brush 300 from the chamber 100. The interface robot 50 may introduce the brush 300 into the chamber 100 through an entrance 110 of the chamber 100 and fix the brush 300 to the stand 200. In addition, the interface robot 50 may remove the brush 300, for which aging has been completed, from the stand 200 and then discharge the same to the outside of the chamber 100. According to one or more embodiments, the interface robot 50 may move the brush 300 between a chamber, where a chemical mechanical polishing (CMP) process is performed, and the chamber 100, where the brush aging process is performed. For example, when the brush aging process is completed in the chamber 100 where the brush aging process is performed, the interface robot 50 may move the brush 300 to the chamber where the CMP process is performed.

According to one or more embodiments, the interface robot 50 may include a robot arm and a holder. The robot arm may be coupled to the holder and have degrees of freedom along X, Y, and Z axes. The holder may hold the brush 300. In some one or more embodiments, the interface robot 50 may be located inside the chamber 100.

In the drawings below, the X-axis direction and the Y-axis direction indicate directions parallel to the upper surface or the lower surface of the chamber 100, and the X-axis direction may be perpendicular to the Y-axis direction. The Z-axis direction may be perpendicular to the upper surface or the lower surface of the chamber 100. Likewise, the Z-axis direction may be perpendicular to the X-Y plane.

In addition, in the drawings below, the first horizontal direction, the second horizontal direction, and the vertical direction may be understood as follows. The first horizontal direction may be understood as the X-axis direction, the second horizontal direction may be understood as the Y-axis direction, and the vertical direction may be understood as the Z-axis direction.

The stand 200 may be a member to which the brush 300 is fixed. The stand 200 may be configured to rotate the brush 300. The stand 200 may rotate the brush 300 by taking the first horizontal direction X as an axis. According to one or more embodiments, the stand 200 may include two columns protruding from the bottom surface of the chamber 100 in the vertical direction Z. The two columns may be spaced apart from each other in the first horizontal direction X. In addition, the distance between the two columns may be substantially the same as the length of the brush 300 in the first horizontal direction X. According to one or more embodiments, springs may be respectively provided on opposing faces of the columns. The brush 300 may be fixed to the stand 200 using the springs.

According to one or more embodiments, the brush 300 may be used to clean the substrate. The brush 300 may include a body 310 and protrusions 330. The brush 300 may include a cylindrical body 310. In some one or more embodiments, the interior of the brush 300 may have an empty tube shape. The brush 300 may include the protrusions 330 arranged apart from each other on the circumferential surface of the body 310 at certain intervals. Similarly, the brush 300 may include the protrusions 330 arranged apart from each other on the side surface of the body 310 at certain intervals. The protrusions 330 may protrude from the side surface of the body 310 in the direction perpendicular to the side surface of the body 310. According to one or more embodiments, the brush 300 that is subject to aging may be a new brush 300, and the protrusions 330 of the new brush 300 may have angular edges. For example, the cross-section of the protrusion 330 of the new brush 300 in the vertical direction Z may be a rectangle. In other words, the edge portions of the protrusion 330 of the new brush 300 may not be rounded.

Mounting portions protruding in the lengthwise direction of the body 310 may be formed on the upper surface and the lower surface of the brush 300. According to one or more embodiments, the mounting portions may be coupled to the springs formed on the columns of the stand 200. To this end, the brush 300 may be fixed to the stand 200.

The aging bar 400 may be configured to slowly polish the circumferential surface of the brush 300. The aging bar 400 may be spaced apart from the ceiling 100_U of the chamber 100 in the vertical direction Z perpendicular to the ceiling 100_U. The aging bar 400 may be fixed to the ceiling 100_U of the chamber 100 through a driving member 420. The driving member 420 may be coupled to the ceiling 100_U of the chamber 100 and the aging bar 400. The driving member 420 may have a shape extending from the ceiling 100_U of the chamber 100 downwards in the vertical direction Z. The driving member 420 may be configured to move the aging bar 400 in the vertical direction Z. According to one or more embodiments, the driving member 420 may include at least any one of a hydraulic cylinder and a linear motor. As the driving member 420 moves the aging bar 400 in the vertical direction Z, the aging bar 400 may come in contact with the brush 300. In some one or more embodiments, a plurality of driving members 420 may be provided. For example, two driving members 420 may be provided apart from each other in the horizontal direction. The two driving members 420 may be coupled to the ceiling 100_U of the chamber 100 and the aging bar 400, respectively. In some one or more embodiments, one driving member 420 may be provided. The driving member 420 may transport the aging bar 400 towards the circumferential surface of the brush 300 and adjust the distance in which the aging bar 400 contacts the brush 300. To this end, the pressure between the aging bar 400 and the protrusions 330 of the brush 300 may be adjusted.

According to one or more embodiments, the aging bar 400 may contact the brush 300 in the vertical direction Z by the driving member 420. In some one or more embodiments, the aging bar 400 may contact the brush 300 in the second horizontal direction Y. In this case, the driving member 420 may move the aging bar 400 in the second horizontal direction Y to make the aging bar 400 come in contact with the brush 300 in the second horizontal direction Y.

According to one or more embodiments, the aging bar 400 may have a flat plate shape. The aging bar 400 may be located such that the flat surface of the aging bar 400 faces the circumferential surface of the brush 300. The length of the aging bar 400 in the lengthwise direction of the aging bar 400 may be greater than that of the brush 300 in the lengthwise direction of the brush 300. Likewise, the distance from an end portion of the aging bar 400 to the other end portion thereof may be greater than the distance from an end portion of the brush 300 to the other end portion thereof. Here, the end portion of the aging bar 400 and the end portion of the brush 300 may be understood as the side surface of each of the aging bar 400 and the brush 300 in the horizontal direction.

Compared to the brush 300, the aging bar 400 may include quartz or a polymer material with higher hardness. Examples of the polymer material may include polypropylene (PP), polyethylene (PE), polyphenylene sulfide (PPS), polyether ether ketone (PEEK), polytetrafluoroethylene (PTFE), or the like.

The nozzle 600 may be configured to discharge a cleaning solution towards the brush 300 fixed to the stand 200. Here, the cleaning solution may be water or a chemical fluid. The nozzle 600 may be fixed to the ceiling 100_U of the chamber 100 through a fixing bar 620. The fixing bar 620 may have a shape extending downwards from the ceiling 100_U of the chamber 100 in the vertical direction. The nozzle 600 may be fixed to the lower portion of the fixing bar 620 and located to discharge the cleaning solution to the surface on which the brush 300 is in contact with the aging bar 400. The level of the nozzle 600 in the vertical direction Z may be higher than the vertical level of the brush 300 fixed to the stand 200.

The sensor 500 may be configured to measure parameters of the protrusion 330. Here, the parameters of the protrusion 330 may be understood as, for example, the cross-sectional area of the protrusion 330, the circumference of the edge of the protrusion 330, the height of the protrusion 330 in the protrusion direction, the amount of foreign materials remaining on the surface of the protrusion 330, and the like. The circumference of the edge of the protrusion 330 may refer to the degree to which the edge is rounded. However, the parameters of the protrusion 330 measured by the sensor 500 are not limited thereto.

According to one or more embodiments, the sensor 500 may face the brush 300. The sensor 500 may be apart from the brush 300 and face the same in the second horizontal direction Y. The cross-sectional area of the surface of the sensor 500 that faces the brush 300 may be less than the cross-sectional area of the surface of the brush 300 that faces the sensor 500.

The level of the sensor 500 in the vertical direction Z may be changed using a height adjusting member 530. For example, when the sensor 500 measures the parameters of the protrusion 330 located at a high vertical level of the brush 300, the height adjusting member 530 may ascend in the vertical direction Z such that the sensor 500 faces the protrusion 330 located at the high vertical level of the brush 300. On the contrary, when the sensor 500 measures the parameters of the protrusion 330 located at a low vertical level of the brush 300, the height adjusting member 530 may descend in the vertical direction Z such that the sensor 500 faces the protrusion 330 located at the low vertical level of the brush 300.

The sensor 500 may move along a rail 510 in the first horizontal direction X. The rail 510 may extend in the direction parallel to the lengthwise direction of the brush 300. The length of the rail 510 in the lengthwise direction may be substantially the same as or greater than the length of the brush 300 in the lengthwise direction of the brush 300. While moving along the rail 510, the sensor 500 may measure the parameters of the protrusions 330 of the brush 300.

The controller 900 may be configured to control the driving member 420 and the stand 200, based on the parameters of the protrusion 330 that are measured by the sensor 500. For example, the controller 900 may control the driving member 420 based on the cross-section of the protrusion 330 along the Y-Z plane, the height of the protrusion 330 in the protrusion direction thereof, the circumference of the edge of the protrusion 330, and the amount of foreign materials remaining on the surface of the protrusion 330 to move the aging bar 400 to make the aging bar 400 come in contact with the circumferential surface of the brush 300, thus adjusting the pressure applied to the brush 300 by the aging bar 400. In addition, the controller 900 may control the rotation speed at which the stand 200 rotates the brush 300. The controller 900 may abrade the protrusion 330 mounted on the stand 200 to achieve a targeted shape, based on the parameters of the protrusion 330 that are provided by the sensor 500. To this end, the height of the protrusion 330 in the protrusion direction may decrease, the edges of the protrusion 330 may be rounded, and the foreign materials remaining on the surface of the protrusion 330 may be effectively removed.

The controller 900 may be realized as hardware, firmware, software, or an arbitrary combination thereof. For example, the controller 900 may include a computing device of a workstation computer, a desktop computer, a laptop, a tablet computer, or the like. The controller 900 may include a simple controller, a complex processor such as a microprocessor, a central processing unit (CPU), or a graphics processing unit (GPU), at least one processor including software, dedicated hardware, or firmware. The controller 900 may be realized using, for example, a general-purpose computer or application-specific hardware such as a Digital Signal Processor (DSP), a Field Programmable Gate Array (FPGA), and an Application Specific Integrated Circuit (ASIC). The controller 900 may be implemented as instructions stored in a machine-readable medium that is readable and executable by one or more processors. Here, the machine-readable medium may include any mechanism configured to store and/or transmit information in a form readable by a machine (e.g., a computing device). For example, the machine-readable medium may include Read Only Memory (ROM), Random Access Memory (RAM), magnetic disk storage media, optical storage media, flash memory devices, electric, optical, acoustic, or other forms of radio signals (e.g., carrier waves, infrared signals, digital signals, etc.) and other arbitrary signals.

In existing apparatuses, a device for aging the brush 300 and the sensor 500 for measuring the aging degree of the brush 300 are located in different regions, leading to a problem in which the brush 300 needs to be frequently moved to the region of the sensor 500 during the aging process of the brush 300. Accordingly, the aging period of the brush 300 may extend, and the aging accuracy of the brush 300 may decrease.

However, in the brush aging apparatus 10 according to one or more embodiments of the disclosure, the sensor 500 included in the same chamber 100 as the brush 300 may allow for frequent measurement of the aging degree of the brush 300, and based on the measurement, the pressure applied to the brush 300 by the aging bar 400 and the rotation speed of the brush 300 may be adjusted; thus, the aging accuracy of the brush 300 may increase. In addition, when the aging degree of the brush 300 needs to be measured during the aging process of the brush 300, the aging degree of the brush 300 may be immediately measured by the sensor 500 in the chamber 100 without detachably attaching the brush 300 to the stand 200. Here, the aging degree refers to the extent to which the protrusion 330 is worn down and may also be understood as a parameter of the protrusion 330. Furthermore, because the brush 300 may be introduced into the chamber 100 or discharged to the outside of the chamber 100, contamination of the brush 300 with foreign materials during the transfer may be prevented. Through an automated aging process of the brush 300, the productivity and accuracy of the aging process of the brush 300 may be improved.

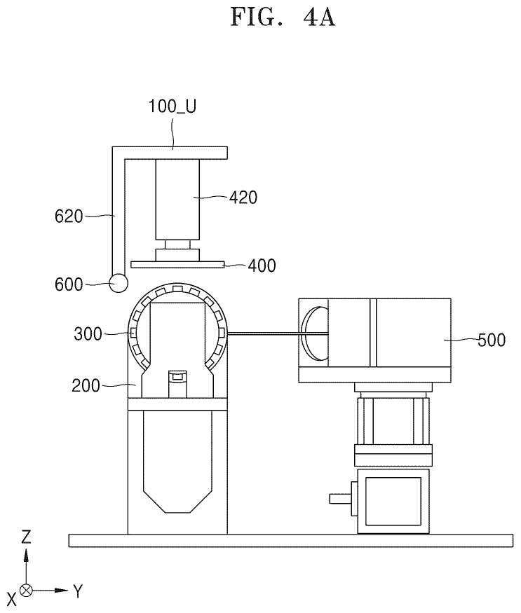

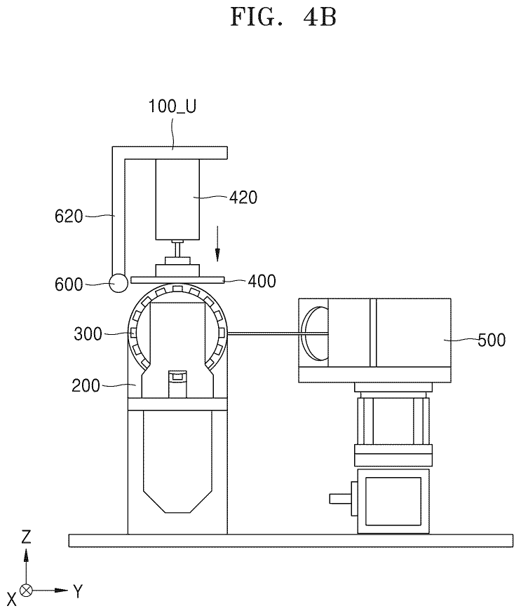

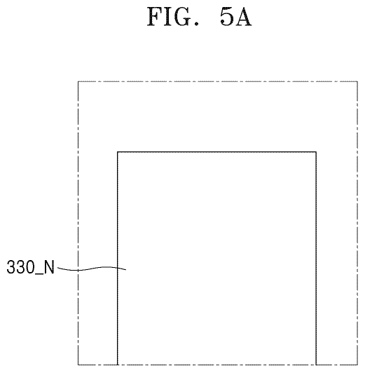

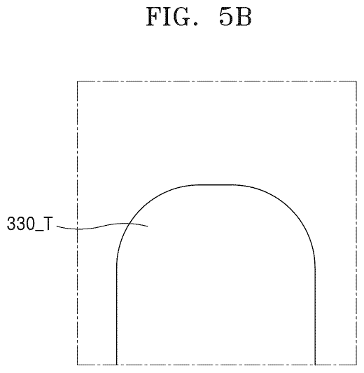

FIGS. 4A and 4B schematically show the operations performed by the brush aging apparatus 10 of FIG. 1. FIGS. 5A and 5B are cross-sectional views showing shape changes of protrusions, according to one or more embodiments; Hereinafter, the descriptions that are the same as those given with reference to FIG. 1 are omitted, and the differences therebetween are mainly described.

Referring to FIGS. 4A and 5A first, immediately after the brush 300 is mounted on the stand 200, the aging bar 400 may be spaced apart from the circumferential surface of the brush 300. According to one or more embodiments, the aging bar 400 may be spaced apart, in the vertical direction Z, from the brush 300 mounted on the stand 200. In this case, the flat surface of the aging bar 400 may face the brush 300 in the vertical direction Z.

In this case, the brush 300 may be a new brush 300 before the aging process starts, and as shown in FIG. 5A, the cross-section of new protrusions 330_N of the new brush 300 in the Y-Z direction may have almost right-angled edges. However, for convenience, FIG. 5A shows that the edges of the cross-section of the new protrusion 330_N in the Y-Z direction are right-angled, and in some one or more embodiments, the edges above may be rounded.

Then, as shown in FIG. 4B, the driving member 420 fixed to the ceiling 100_U may move the aging bar 400 downwards in the vertical direction Z so that the aging bar 400 may come in contact with the circumferential surface of the brush 300. The aging bar 400 may contact the circumferential surface of the brush 300 through the driving member 420, and because of the descending of the aging bar 400 in the vertical direction Z, the aging bar 400 may apply certain pressure to the circumferential surface of the brush 300. To this end, the protrusions 330 formed on the circumferential surface of the brush 300 may be worn down, and the aging of the brush 300 may proceed. As the aging process of the brush 300 continues, the brush 300 may have protrusions 330_T that are abraded as in FIG. 5B. The abraded protrusion 330_T may have a height in the vertical direction Z that is reduced compared to the new protrusion 330_N, and the edge portions of the abraded protrusion 330_T may also be rounded more than those of the new protrusion 330_N.

In some one or more embodiments, before the aging process of the brush 300 is performed, the flat surface of the aging bar 400 may face the brush 300 in the second horizontal direction Y, and in this case, the aging bar 400 may be spaced apart from the brush 300 in the second horizontal direction Y. Then, when the aging process of the brush 300 is performed, the driving member 420 may move the aging bar 400 in the second horizontal direction Y so that the aging bar 400 may come in contact with the circumferential surface of the brush 300.

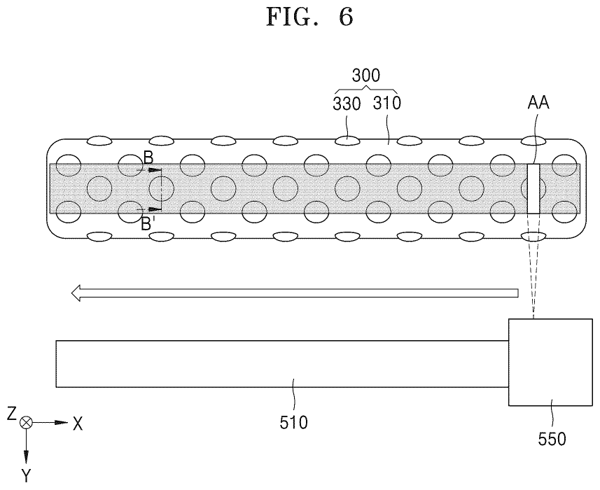

FIG. 6 schematically shows the operation of a sensor, according to one or more embodiments. FIG. 7A schematically shows a region AA of FIG. 6. FIG. 7B is a cross-sectional view taken along a line B-B′ of FIG. 6. Hereinafter, the descriptions that are the same as those given with reference to FIGS. 1 to 5B are omitted, and the differences therebetween are mainly described.

Referring to FIGS. 6 to 7B, while moving along the rail 510, the sensor 500 may measure the parameters of the protrusions 330 formed on the circumferential surface of the aging bar 400. In this case, the sensor 500 may move from an end portion of the rail 510 to the other end portion thereof, thus measuring the parameters of the protrusions 330 of the aging bar 400. In this case, the protrusions 330 measured simultaneously may be the protrusions 330 formed in a row in the first horizontal direction X and may be understood as the protrusions 330 in the region AA of FIGS. 6 and 7A. After the measurement of the parameters of the protrusions 330 are completed, the protrusions 330 formed in other regions of the brush 300 may start being measured as the brush 300 rotates. In addition, the sensor 500 may store the shape of the protrusion 330 as either an image shown in FIG. 7A or a graph based on the Y-Z cross-section of FIG. 7B.

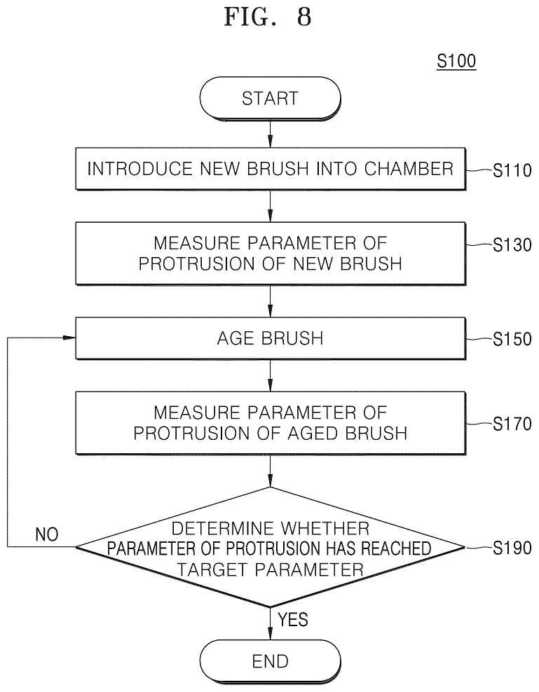

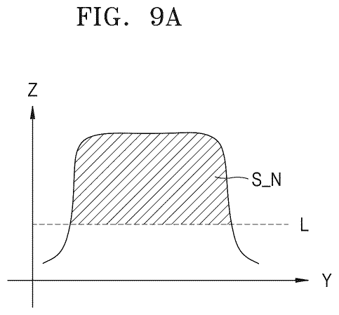

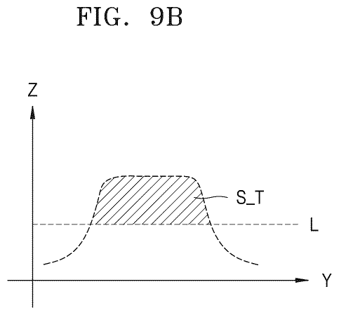

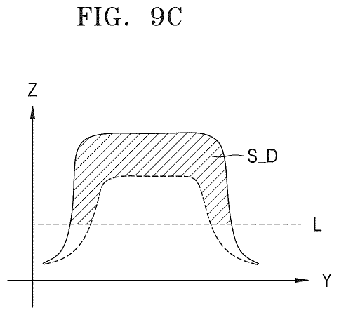

FIG. 8 is a schematic flowchart of a brush aging method. FIGS. 9A to 9C are cross-sectional views to explain shape changes of protrusions according to brush aging. Hereinafter, the descriptions that are the same as those given with reference to FIGS. 1 to 7B are omitted, and the differences therebetween are mainly described.

Referring to FIGS. 1, 8, and 9A to 9C, a brush aging method S100 may include operation S110 of introducing the new brush 300 into the chamber 100, operation S130 of measuring the parameter of the protrusion 330 of the new brush 300, operation S150 of aging the brush, operation S170 of measuring the parameter of the protrusion 330 of the aged brush 300, and operation S190 of determining whether the parameter of the protrusion 330 has reached a target parameter.

First of all, in operation S110, the new brush 300 requiring aging is introduced into the chamber 100. In this case, the new brush 300 may be transferred into the chamber 100 using the interface robot 50. The new brush 300 may be fixed by the stand 200. Then, in operation S130, the parameters of the protrusions 330 formed on the brush 300 are measured by the sensor 500. While moving along the rail 510, the sensor 500 may measure the parameters of the protrusions 330 formed on the circumferential surface of the brush 300. In this case, the sensor 500 may measure the parameters of the protrusions 330 formed on the circumferential surface of the brush 300 in a row in the first horizontal direction X. After the parameters of the protrusions 330 formed in a row have been measured, the stand 200 may rotate the brush 300. Due to the rotation of the stand 200, the protrusions 330 formed in a row and the protrusions 330 formed in other columns may be located to face the sensor 500. Then, the sensor 500 may measure the parameters of the protrusions 330 newly facing the sensor 500, due to the rotation of the stand 200. When the rotation of the stand 200 is completed to 360 degrees as the above process is repeated, the measurements of the parameters of the protrusions 330 of the new brush 300 may be completed.

Next, in operation S150, the aging of the brush 300 proceeds based on the parameters of the protrusions 330 that are measured by the sensor 500. According to one or more embodiments, the controller 900 may control the pressure applied to the brush 300 by the aging bar 400 and the rotation speed of the brush 300, based on the cross-sectional area of the Y-Z plane of the protrusion 330. For example, the controller 900 may determine the pressure applied to the brush 300 by the aging bar 400 and the rotation speed of the brush 300, based on a value of the cross-sectional area S_D shown in FIG. 9C, which indicates the difference between the cross-sectional area S_N of the protrusion 330 of the new brush 300 along the Y-Z plane, shown in FIG. 9A, and the cross-sectional area S_T of the protrusion 330 of the target brush 300 along the Y-Z plane, shown in FIG. 9B. In addition, the cross-sectional areas S_N, S_T, and S_D shown in FIGS. 9A to 9C may be understood as widths in the reference line L extending in the Y-axis direction. They are only examples in which the controller 900 determines the pressure applied to the brush 300 by the aging bar 400 and the rotation speed of the brush 300, and the controller 900 may control the pressure applied to the brush 300 by the aging bar 400 and the rotation speed of the brush 300, based on various parameters of the protrusions 330 that are measured by the sensor 500.

After the aging of the brush 300 has been completed, the parameter of the protrusion 330 of the aged brush 300 is measured in operation S170. The sensor 500 may measure the parameter of the protrusion 330 of the aged brush 300 through the processes performed when the parameters of the protrusions 330 of the new brush 300 are measured. In this case, the aging bar 400 may be positioned at a certain distance away from the brush 300.

Then, in operation S190, the controller 900 determines whether the parameter of the aged protrusion 330 has reached the target parameter. When the parameter of the aged protrusion 330 fails to reach the target parameter, operation S150 of aging the brush 300 is performed again. In this case, the aging degree of the brush 300 may be re-calculated based on the parameter of the aged protrusion 330, and the remaining operations may continue. When the parameter of the aged protrusion 330 reaches the target parameter, the aging process of the brush 300 is completed, and the brush can be removed from the chamber.

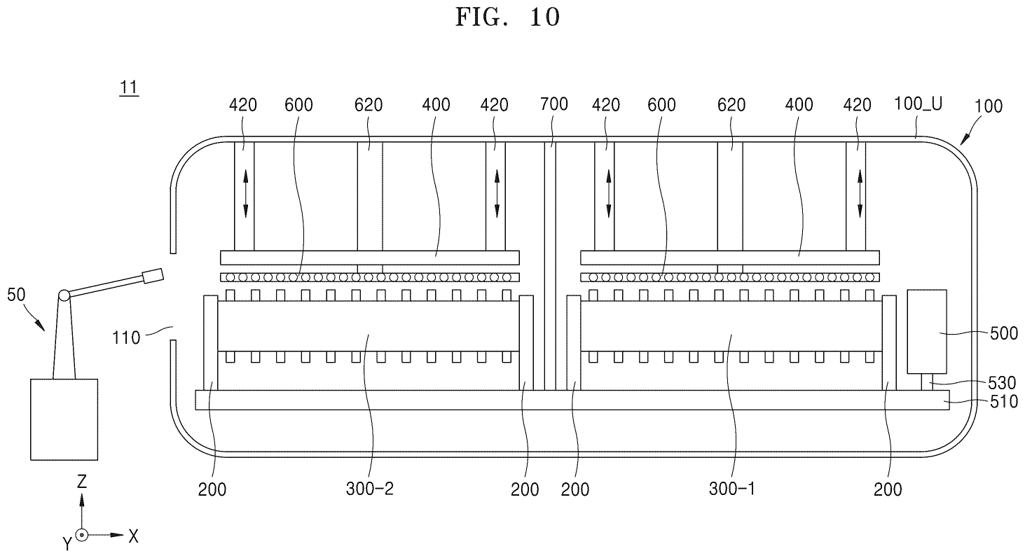

FIG. 10 is a schematic cross-sectional view of a brush aging apparatus 11 according to one or more embodiments. Hereinafter, the descriptions that are the same as those given with reference to FIGS. 1 to 9C are omitted, and the differences therebetween are mainly described.

Referring to FIG. 10, the brush aging apparatus 11 may include the chamber 100, the interface robot 50, a plurality of brushes 300-1 and 300-2, a plurality of aging bars 400, a plurality of stands 200, a plurality of nozzles 600, the sensor 500, a shield 700, and the controller 900.

The chamber 100 may include an internal process space. According to one or more embodiments, the chamber 100 may provide an internal space to accommodate the brushes 300-1 and 300-2, the aging bars 400, the stands 200, the nozzles 600, the sensor 500, and the shield 700. For example, two stands 200 may be provided inside the chamber 100, and the brushes 300-1 and 300-2 may be respectively mounted on the stands 200.

The interface robot 50 may be configured to introduce the brushes 300-1 and 300-2 into the chamber 100 or discharge the brushes 300-1 and 300-2 to the outside of the chamber 100. According to one or more embodiments, the interface robot 50 may mount one brush 300-1 on any one of the stands 200 and the other brush 300-2 on the other stand 200. In some one or more embodiments, the interface robot 50 may hold the brushes 300-1 and 300-2 and mount any one of the brushes, for example, the brush 300-1, on any one of the stands 200 and the other brush 300-2 on the other stand 200.

The stands 200 may be configured to respectively fix the brushes 300-1 and 300-2. The stands 200 may be configured to respectively rotate the mounted brushes 300-1 and 300-2. The stands 200 may rotate the brushes 300-1 and 300-2 by taking the first horizontal direction X as an axis.

Each of the brushes 300-1 and 300-2 may be used to clean the substrate. According to one or more embodiments, the brushes 300-1 and 300-2 that are subject to aging may be new brushes 300-1 and 300-2.

Each aging bar 400 may be configured to gradually abrade the circumferential surfaces of the brushes 300-1 and 300-2. Each aging bar 400 may be located apart from the ceiling 100_U of the chamber 100 in the vertical direction Z. The aging bars 400 may be spaced apart from each other in the first horizontal direction X. Each aging bar 400 may be fixed from the ceiling 100_U of the chamber 100 through the driving member 420. The driving member 420 may be configured to move the aging bar 400 in the vertical direction Z. As the driving member 420 moves the aging bar 400 in the vertical direction Z, the aging bar 400 may contact the brushes 300-1 and 300-2.

According to one or more embodiments, each aging bar 400 may have a flat plate shape. Each aging bar 400 may be located such that the flat surface of the aging bar 400 may face the circumferential surfaces of the brushes 300-1 and 300-2. According to one or more embodiments, the length of each of the aging bars 400 in the lengthwise direction may be greater than the lengths of each of the brushes 300-1 and 300-2 in the lengthwise direction.

The nozzle 600 may be provided in plurality. Any one of the nozzles 600 may be located adjacent to any one of the brushes 300-1 and 300-2, for example, the brush 300-1, and another nozzle 600 may be located adjacent to the other brush 300-2. Each nozzle 600 may be fixed to the ceiling 100_U of the chamber 100 through the fixing bar 620. The nozzle 600 may discharge the cleaning solution to the surface on which the brushes 300-1 and 300-2 contact the aging bar 400.

The sensor 500 may be located to face the circumferential surfaces of the brushes 300-1 and 300-2. For example, the sensor 500 may be spaced apart from the brushes 300-1 and 300-2 in the second horizontal direction Y. The level of the sensor 500 in the vertical direction Z may be changed using a height adjusting member 530. The sensor 500 may move along the rail 510 in the first horizontal direction X. While moving the rail 510, the sensor 500 may measure the parameters of the brushes 300-1 and 300-2. According to one or more embodiments, the length of the rail 510 in the first horizontal direction X may be substantially the same as or greater than the sum of the lengths of the brushes 300-1 and 300-2 in the chamber 100 in the first horizontal direction X.

The shield 700 may be located between the stands 200. The shield 700 may prevent particles, which are generated during the aging of the brush 300-1, or the cleaning solution from spreading to the other brush 300-2. According to one or more embodiments, the shield 700 may have a shape extending downwards from the ceiling 100_U of the chamber 100 in the vertical direction Z. According to one or more embodiments, the brushes 300-1 and 300-2 may be spaced apart from each other in the first horizontal direction X with the shield 700 therebetween.

In the brush aging apparatus 11, the brushes 300-1 and 300-2 may be mounted on the stands 200 within the chamber 100, and aging may be performed independently for each of the brushes 300-1 and 300-2. Accordingly, the aging efficiency of the brushes 300-1 and 300-2 may be improved.

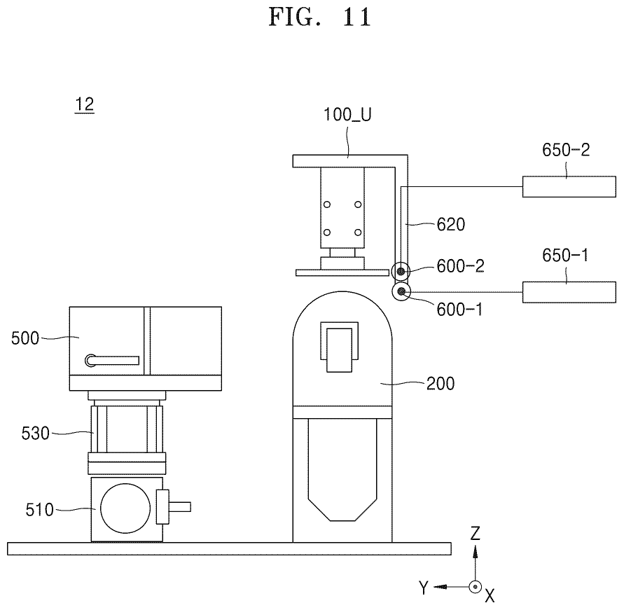

FIG. 11 is a schematic cross-sectional view of a brush aging apparatus 12 according to one or more embodiments. Hereinafter, the descriptions that are the same as those given with reference to FIGS. 1 to 10 are omitted, and the differences therebetween are mainly described.

Referring to FIG. 11, the brush aging apparatus 12 may include a plurality of nozzles 600-1 and 600-2. The nozzles 600-1 and 600-2 may be coupled to one fixing bar 620. According to one or more embodiments, the nozzles 600-1 and 600-2 may be configured to discharge different liquids. For example, any one of the nozzles 600-1 may discharge water, while the other nozzle 600-2 may discharge a chemical fluid. In this case, the nozzle 600-1 discharging water may be connected to a first fluid supply device 650-1, and the nozzle 600-2 discharging the chemical fluid may be connected to a second fluid supply device 650-2. Here, the first fluid supply device 650-1 may be configured to store water, and the second fluid supply device 650-2 may be configured to store the chemical fluid.

Compared to discharging water or a chemical liquid through a single nozzle, the brush aging apparatus 12 discharges a chemical liquid or water through separate nozzles 600-1 and 600-2, which helps prevent particle generation or contamination. Consequently, the reliability of the brush aging apparatus 12 may be improved.

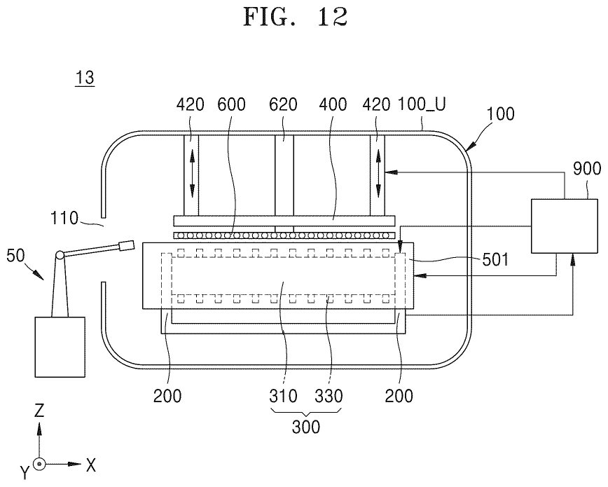

FIG. 12 is a schematic cross-sectional view of a brush aging apparatus 13 according to one or more embodiments. Hereinafter, the descriptions that are the same as those given with reference to FIGS. 1 to 11 are omitted, and the differences therebetween are mainly described.

Referring to FIG. 12, the brush aging apparatus 13 may include a sensor 501 provided within the chamber 100. The sensor 501 may face the brush 300. According to one or more embodiments, the cross-sectional area of the surface of the sensor 501 that faces the brush 300 may be greater than or equal to the cross-sectional area of the surface of the brush 300 that faces the sensor 501. To this end, the sensor 501 may measure the parameters of the protrusions 330 formed on the brush 300 simultaneously. In addition, the brush aging apparatus 13 may not include the height adjusting member 530 and the rail 510 shown in FIGS. 1 to 11. Because the sensor 501 may measure the parameters of the protrusions 330 simultaneously, the efficiency of the brush aging apparatus 13 may be improved.

While the disclosure has been particularly shown and described with reference to one or more embodiments thereof, it will be understood that various changes in form and details may be made therein without departing from the spirit and scope of the following claims.

What is claimed is:

1. A brush aging apparatus comprising:
a chamber configured to provide a process space; and
inside the process space:
a brush comprising a plurality of protrusions protruding in a direction perpendicular to a circumferential surface of the brush;
a stand detachably coupled to the brush and configured to rotate the brush by taking a lengthwise direction of the brush as a rotation axis;
an aging bar configured to abrade the plurality of protrusions;
a driving member coupled to the aging bar and configured to move the aging bar to make the aging bar contact or be spaced apart from at least any one of the plurality of protrusions of the brush;
a nozzle configured to discharge a cleaning solution to an interface where the brush contacts the aging bar; and
a sensor spaced apart from the brush and configured to measure parameters of the plurality of protrusions.

2. The brush aging apparatus of claim 1, wherein a cross-sectional area of a surface of the sensor that faces the brush is less than a cross-sectional area of a surface of the brush that faces the sensor, and
the sensor is configured to move along a rail extending in a direction parallel to the lengthwise direction of the brush.

3. The brush aging apparatus of claim 1, wherein a cross-sectional area of a surface of the sensor that faces the brush is substantially a same as a cross-sectional area of a surface of the brush that faces the sensor.

4. The brush aging apparatus of claim 1, wherein the driving member is coupled to a ceiling of the chamber and configured to move the aging bar in a vertical direction, and
the aging bar overlaps the brush in the vertical direction.

5. The brush aging apparatus of claim 4, wherein the nozzle is located at a higher vertical level than an upper surface of the stand.

6. The brush aging apparatus of claim 1, further comprising:
a plurality of the nozzle comprising:
a first nozzle configured to discharge water to the brush; and
a second nozzle configured to discharge a chemical fluid to the brush.

7. The brush aging apparatus of claim 1, further comprising:
at least one processor; and
memory storing instructions that, when executed by the at least one processor, cause the at least one processor to control pressure applied to the brush by the aging bar and rotation speed of the brush, based on the parameters of the plurality of protrusions measured by the sensor.

8. The brush aging apparatus of claim 1, further comprising:
a plurality of the brush;
a shield between the plurality of brushes;
a plurality of the stand;
a plurality of the driving member; and
a plurality of the aging bar,
wherein the plurality of brushes are respectively fixed to the plurality of stands and located in a row in a first horizontal direction, and the plurality of aging bars respectively contact or are spaced apart from circumferential surfaces of the plurality of brushes by the plurality of driving members.

9. The brush aging apparatus of claim 8, further comprising:
a rail extending in a direction parallel to the lengthwise direction of the brush,
wherein a length of the rail in the lengthwise direction is greater than or equal to a sum of lengths of the plurality of brushes in the first horizontal direction.

10. The brush aging apparatus of claim 1, wherein the parameters comprise at least any one of a cross-sectional area of the plurality of protrusions of the brush according to a Y-Z plane, a height of the plurality of protrusions in a protrusion direction, a degree to which edges of the plurality of protrusions are rounded, and an amount of foreign materials left on a surface of the plurality of protrusions.

11. A brush aging method comprising:
introducing a brush into a chamber, the brush being a new brush;
measuring a parameter of a protrusion of the new brush through a sensor inside the chamber;
performing aging for the brush based on the parameter to convert the new brush into an aged brush;
measuring the parameter of the protrusion of the aged brush through the sensor;
determining, by using at least one processor, whether the parameter has reached a target parameter;
when the parameter fails to reach the target parameter, performing again the aging for the aged brush based on the parameter; and
when the parameter reaches the target parameter, removing the aged brush from the chamber.

12. The brush aging method of claim 11, wherein the brush is fixed by a stand, and the stand is configured to rotate the brush.

13. The brush aging method of claim 12, wherein the instructions further cause the at least one processor to control pressure applied by an aging bar to the brush and rotation speed of the brush, based on the parameter of the protrusion that is measured by the sensor.

14. The brush aging method of claim 11, wherein the aging bar contacts or is spaced apart from the brush by a driving member,
the driving member is coupled to a ceiling of the chamber, and
the aging bar overlaps the brush in a vertical direction.

15. The brush aging method of claim 11, wherein the sensor moves along a rail extending in a direction parallel to a lengthwise direction of the brush, the sensor being configured to measure the parameter of the protrusion of the brush.

16. The brush aging method of claim 11, wherein a cross-sectional area of a surface of the sensor that faces the brush is substantially a same as a cross-sectional area of a surface of the brush that faces the sensor, and
while fixed, the sensor is configured to measure the parameter of the protrusion of the brush.

17. The brush aging method of claim 11, wherein the parameter comprises at least any one of a cross-sectional area of the protrusion of the brush according to a Y-Z plane, a height of the protrusion in a protrusion direction, a degree to which edges of the protrusion are rounded, and an amount of foreign materials left on a surface of the protrusion.

18. A brush aging apparatus comprising:
a chamber configured to provide a process space;
inside the process space:
a brush comprising a plurality of protrusions protruding in a direction perpendicular to a circumferential surface of the brush;
a stand detachably coupled to the brush and configured to rotate the brush by taking a lengthwise direction of the brush as a rotation axis;
an aging bar configured to abrade the plurality of protrusions, having a flat shape, and placed such that a flat surface of the aging bar faces the circumferential surface of the brush;
a driving member coupled to a ceiling of the chamber and the aging bar and configured to move the aging bar in a vertical direction to make the aging bar come in contact with or be spaced apart from at least any one of the plurality of protrusions of the brush;
a nozzle configured to discharge a cleaning solution to an interface where the brush contacts the aging bar;
a sensor spaced apart from the brush and configured to measure parameters of the plurality of protrusions;
a height adjusting member configured to adjust a location of the sensor in the vertical direction; and
a rail extending in a direction parallel to the lengthwise direction of the brush and providing a path along which the sensor moves in the lengthwise direction of the brush;
at least one processor; and
memory storing instructions that, when executed by the at least one processor, cause the at least one processor to control pressure applied to the brush by the aging bar and rotation speed of the brush, based on the parameters of the plurality of protrusions that are measured by the sensor,
wherein the parameters comprise at least any one of a cross-sectional area of the plurality of protrusions of the brush according to a Y-Z plane, a height of the plurality of protrusions in a protrusion direction, a degree to which edges of the plurality of protrusions are rounded, and an amount of foreign materials left on a surface of the plurality of protrusions.

19. The brush aging apparatus of claim 18, further comprising:
a plurality of the nozzle comprising:
a first nozzle configured to discharge water to the brush; and
a second nozzle configured to discharge a chemical fluid to the brush.

20. The brush aging apparatus of claim 18, further comprising:
a plurality of the brush;
a shield between the plurality of brushes;
a plurality of the stand;
a plurality of the driving member; and
a plurality of the aging bar,
wherein the plurality of brushes are respectively fixed to the plurality of stands and located in a row in a first horizontal direction, and the plurality of aging bars respectively contact or are spaced apart from circumferential surfaces of the plurality of brushes by the plurality of driving members.
